(19) United States
(12) Patent Application Publication
(10) Pub. No.: US 2012/0152607 A1
(43) Pub. Date: Jun. 21, 2012

(54) PRINTED CIRCUIT BOARD

(75) Inventors: YUNG-CHIEH CHEN, Tu-Cheng (TW); SHOU-KUO HSU, Tu-Cheng (TW)

(73) Assignee: HON HAI PRECISION INDUSTRY CO., LTD., Tu-Cheng (TW)

(21) Appl. No.: 12/979,340

(22) Filed: Dec. 28, 2010

(30) Foreign Application Priority Data
Dec. 17, 2010 (TW) 99144636

(51) Int. Cl. H05K 1/11

(52) U.S. Cl. 174/266

(57) ABSTRACT

A printed circuit board (PCB) includes first and second signal layers. First and second pairs of signal transmission lines are respectively laid out on the first and second signal layers. The first pair of signal transmission lines includes first positive and negative differential signal transmission lines. The second pair of signal transmission lines includes second positive and negative differential signal transmission lines. The first positive differential signal transmission line is electrically connected to the second negative differential signal transmission line by a first vertical interconnect access (via). The first negative differential signal transmission line is electrically connected to the second positive differential signal transmission line by a second via. An angle between a centerline of each of the first via and second via and a surface of the PCB is an acute angle.

### BACKGROUND

1. Technical Field

The present disclosure relates to a printed circuit board (PCB).

2. Description of Related Art

Via stands for “vertical interconnect access” which is a vertical electrical connection between different layers of conductors in PCB design. Vias are pads with plated holes that provide electrical connections between copper traces on different layers of the PCB. Generally speaking, vias are vertical to the layers of the PCB. After differential signal transmission lines are laid out on signal layers, sometimes, polarity of the differential signal transmission lines needs to be changed. Referring to FIG. 1, for example, a positive line 21 on a first layer 2 is electrically connected to a negative line 32 on a second layer 3 by a first vertical via 1; a negative line 22 on the first layer 2 is electrically connected to a positive line 31 on the second layer 3 by a second vertical via 4. In order to satisfy that lengths of two differential signal transmission lines on the PCB are equal, one of the two differential signal transmission lines need to be laid out in a curved line 22. However, this increases space needed for the differential signal transmission lines and wastes space of the PCB.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic view of a related-art printed circuit board (PCB).

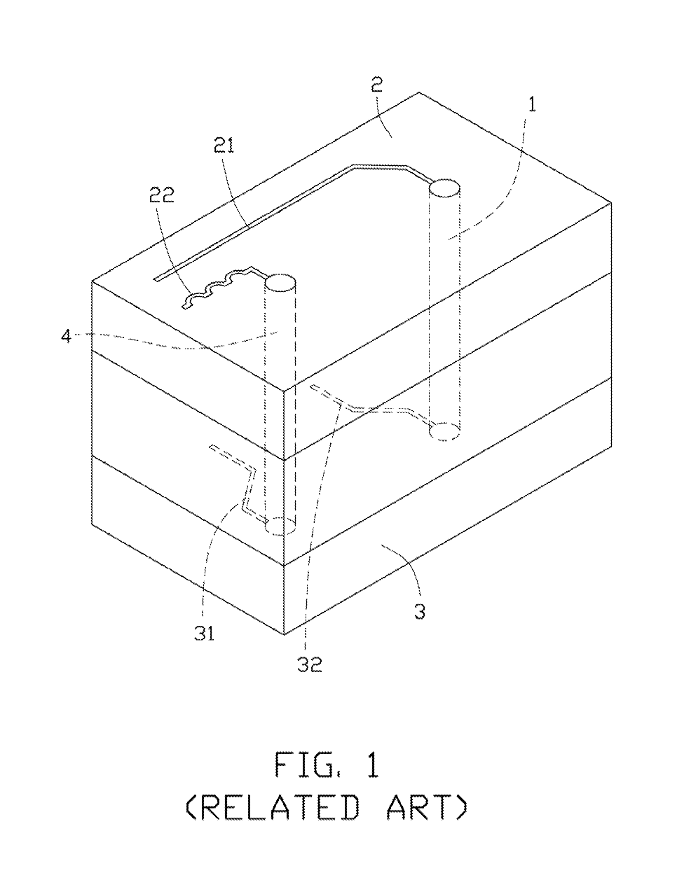

FIG. 2 is a schematic view of an exemplary embodiment of a PCB.

FIG. 3 is a cross-sectional, schematic view of the PCB of FIG. 2.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

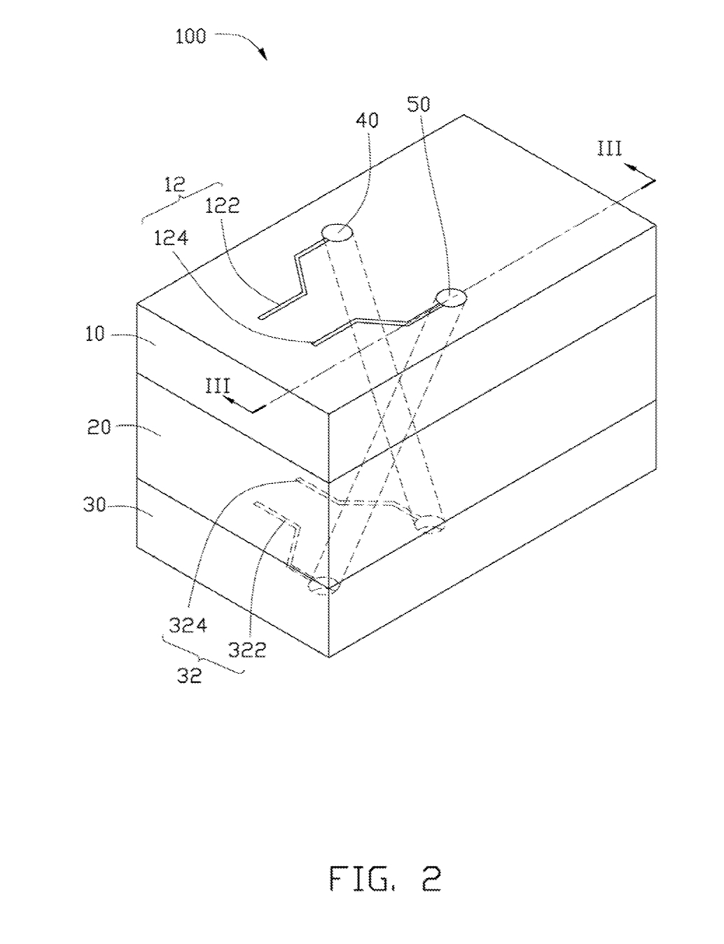

Referring to FIG. 2, an embodiment of a printed circuit board (PCB) 100 includes a first signal layer 10, a second signal layer 30, and a dielectric layer 20 sandwiched between the first signal layer 10 and the second signal layer 30. A first pair of signal transmission lines 12 is laid out on the first signal layer 10. A second pair of signal transmission lines 32 is laid out on the second signal layer 30. The first pair of signal transmission lines 12 includes a first positive differential signal transmission line 122 and a first negative differential signal transmission line 124. The second pair of signal transmission lines 32 includes a second positive differential signal transmission line 322 and a second negative differential signal transmission line 324. The first positive differential signal transmission line 122 is electrically connected to the second negative differential signal transmission line 324 through a first vertical interconnect access (via) 40. The first negative differential signal transmission line 124 is electrically connected to the second positive differential signal transmission line 322 through a second via 50.

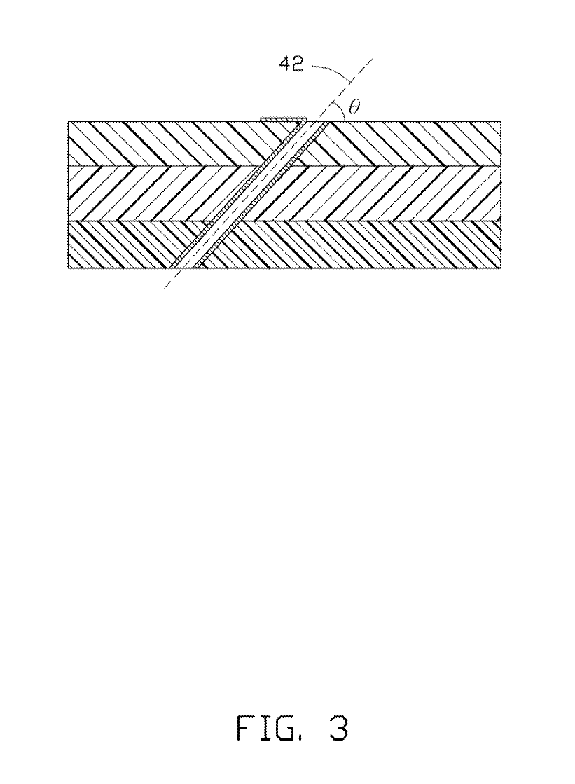

Referring to FIG. 3, an angle between a centerline 42 of the first via 40 and the first signal layer 10 of the PCB 100 is an acute angle θ. An angle between a centerline of the second via 50 and the first signal layer 10 of the PCB 100 is an acute angle (not shown). A connection line between the first via 40 and the second via 50 on the first signal layer 10 is perpendicular to a connection line between the first via 40 and the second via 50 on the second signal layer 10.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A printed circuit board (PCB) comprising:
a first signal layer, wherein a first pair of signal transmission lines is laid out on the first signal layer, the first pair of signal transmission lines comprises a first positive differential signal transmission line and a first negative differential signal transmission line; and
a second signal layer, wherein a second pair of signal transmission lines is laid out on the second signal transmission layer, the second pair of signal transmission lines comprises a second positive differential signal transmission line and a second negative differential signal transmission line;
wherein the first positive differential signal transmission line is electrically connected to the second negative differential signal transmission line by a first vertical interconnect access (via), the first negative differential signal transmission line is electrically connected to the second positive differential signal transmission line by a second via, an angle between a centerline of each of the first via and second via and the first signal layer of the PCB is an acute angle.

2. The PCB of claim 1, wherein a connection line between the first via and the second via on the first signal layer is perpendicular to a connection line between the first via and the second via on the second signal layer.
